(19) United States
(12) Patent Application Publication
(10) Pub. No.: US 2025/0110024 A1
(43) Pub. Date: Apr. 3, 2025

(54) METHOD AND DEVICE FOR LOAD REJECTION TEST FOR PUMPED STORAGE GROUP, APPARATUS AND MEDIUM

(71) Applicant: CSG POWER GENERATION CO., LTD. MAINT. AND TEST CO., Guangzhou (CN)

(72) Inventors: Xiangdong LIU, Guangzhou (CN); Qing LI, Guangzhou (CN); Yu GONG, Guangzhou (CN); Peng LING, Guangzhou (CN); Yakang ZHAO, Guangzhou (CN); Yalin JIA, Guangzhou (CN); Liangliang NIE, Guangzhou (CN); Minghao HUANG, Guangzhou (CN)

(73) Assignee: CSG POWER GENERATION CO., LTD. MAINT. AND TEST CO., Guangzhou (CN)

(21) Appl. No.: 18/705,623

(22) PCT Filed: Oct. 31, 2023
(86) PCT No.: PCT/CN2023/128549

§ 371 Date: Apr. 29, 2024

(30) Foreign Application Priority Data
Nov. 25, 2022 (CN) 202211486748.8

(51) Int. Cl. G01M 99/00

(52) U.S. Cl. CPC G01M 99/008

(57) ABSTRACT

A method and device for a load rejection test for a pumped storage group, an apparatus and a medium. The method includes: determining a probability distribution model of at least one known random variable corresponding to a target pumped storage group, and determining an origin moment of the target random variable based on each probability distribution model; determining semi-invariants of the target random variable based on the origin moment of the target random variable; determining a probability density function of the target random variable based on the semi-invariants, and determining an overall offset risk value of the target random variable; determining an objective function based on the overall offset risk value, and determining a combination of target decision contents in the load rejection test for the target pumped storage group, so as to perform the load rejection test on the target pumped storage group.

### TECHNICAL FIELD

The present disclosure relates to the field of load rejection technologies for a pumped storage group, and more particularly, to a method and device for a load rejection test for a pumped storage group, an apparatus and a medium.

### BACKGROUND

Load rejection test refers to a test in which a generator suddenly loses a load under different loads to evaluate dynamic characteristics of the generator. Through the load rejection test, a group, which is newly put into operation, can check whether a rising group speed value, a rising volute pressure value and a governor regulating time meet requirements for a contract or design, and check the guide vane closing law, and a de-excitation effect of the generator under a load.

The load rejection test is a very important and dangerous test project in start-up commissioning of a new pumped storage group. At present, only several load points are selected for test in the load rejection test, which are representative to a certain extent, but cannot fully and truly reflect actual working conditions. In macroscopic view, a hydraulic condition, and mechanical and electrical parameters of the group are definite in a certain period, but in microcosmic view, the hydraulic condition and the mechanical and electrical parameters of the group will change at any time under the influence of various factors, which will lead to random fluctuation of various parameters in the load rejection process of the group.

How to accurately determine a combination of decision contents in the load rejection test for the pumped storage group to perform an optimal load rejection test for the pumped storage group is the focus of the industry research.

### SUMMARY

Embodiments of the present disclosure provide a method and device for a load rejection test for a pumped storage group, an apparatus and a medium, so as to accurately determine a combination of decision contents in the load rejection test for the pumped storage group, and then perform an optimal load rejection test on the pumped storage group.

According to an aspect of embodiments of the present disclosure, there is provided a method for a load rejection test for a pumped storage group. The method includes:
determining a probability distribution model of at least one known random variable corresponding to a target pumped storage group, and determining an origin moment of the target random variable based on each probability distribution model, the target random variable being an undetermined random variable in the load rejection test for the target pumped storage group;
determining semi-invariants of the target random variable based on the origin moment of the target random variable;
determining a probability density function of the target random variable based on the semi-invariants, and determining an overall offset risk value of the target random variable based on the probability density function; and determining an objective function based on the overall offset risk value, and determining a combination of target decision contents in the load rejection test for the target pumped storage group based on the objective function, so as to perform the load rejection test on the target pumped storage group based on the combination of the target decision contents.

According to another aspect of embodiments of the present disclosure, there is provided a device for a load rejection test for a pumped storage group. The device includes:
a probability distribution model determination module configured to determine a probability distribution model of at least one known random variable corresponding to a target pumped storage group, and determine an origin moment of the target random variable based on each probability distribution model, the target random variable being an undetermined random variable in the load rejection test for the target pumped storage group;
a semi-invariant determination module configured to determine semi-invariants of the target random variable based on the origin moment of the target random variable;
an overall offset risk value determination module configured to determine a probability density function of the target random variable based on the semi-invariants, and determine an overall offset risk value of the target random variable based on the probability density function;
a target decision content combination determination module configured to determine an objective function based on the overall offset risk value, and determine a combination of target decision contents in the load rejection test for the target pumped storage group based on the objective function, so as to perform the load rejection test on the target pumped storage group based on the combination of the target decision contents.

According to a further aspect of embodiments of the present disclosure, there is provided an electronic apparatus. The electronic apparatus includes:
at least one processor; and
a memory communicatively connected to the at least one processor.

The memory stores a computer program executable by the at least one processor, and the computer program, when executed by the at least one processor, causes the at least one processor to implement the method for the load rejection test for the pumped storage group according to any of the embodiments of the present disclosure.

According to a further aspect of embodiments of the present disclosure, there is provided a computer-readable storage medium storing computer instructions. The computer instructions are configured to cause, when executed by a processor, the processor to implement the method for the load rejection test for the pumped storage group according to any of the embodiments of the present disclosure.

In the technical solution provided by the embodiments of the present disclosure, the probability distribution model of the at least one known random variable corresponding to the target pumped storage group is determined, the origin moment of the target random variable is determined based on each probability distribution model, the semi-invariants of the target random variable are determined based on the origin moment of the target random variable, the probability density function of the target random variable is determined based on the semi-invariants, the overall offset risk value of the target random variable is determined based on the probability density function, the objective function is determined based on the overall offset risk value, and the combination of the target decision contents in the load rejection test for the target pumped storage group is determined based on the objective function, so as to perform the load rejection test on the target pumped storage group based on the combination of the target decision contents. As a result, the combination of decision contents in the load rejection test for the pumped storage group can be accurately determined, and an optimal load rejection test on the pumped storage group can be performed.

It should be understood that the content described in this section is not intended to identify key or important features of the embodiments of the present disclosure, nor is it intended to limit the scope of the present disclosure. Other features of the present disclosure will be readily understood from the following description.

### BRIEF DESCRIPTION OF THE DRAWINGS

To describe the technical solutions in the embodiments of the present disclosure more clearly, the following briefly describes the accompanying drawings required to describe the embodiments. Apparently, the accompanying drawings in the following description show merely some embodiments of the present disclosure, and persons of ordinary skill in the art may still obtain other drawings based on these accompanying drawings without creative efforts.

FIG. 1 is a flow diagram illustrating a method for a load rejection test for a pumped storage group according to a first embodiment of the present disclosure.

FIG. 2 is a flow diagram illustrating the method for the load rejection test for the pumped storage group according to the first embodiment of the present disclosure.

FIG. 3 is a schematic diagram illustrating a configuration of a device for a load rejection test for a pumped storage group according to a second embodiment of the present disclosure.

FIG. 4 is a schematic diagram illustrating a configuration of an electronic apparatus for implementing the method for the load rejection test for the pumped storage group according to an embodiment of the present disclosure.

### DETAILED DESCRIPTION OF THE EMBODIMENTS

In order to enable persons of ordinary skill in the art to better understand technical solutions proposed in the present disclosure, the technical solutions in the embodiments of the present disclosure will be clearly and completely described below with reference to the accompanying drawings in the embodiments of the present disclosure. It is clear that the described embodiments are only some but not all of the embodiments of the present disclosure. Based on the embodiments of the present disclosure, all other embodiments obtained by persons of ordinary skill in the art without creative efforts should fall within the scope of protection of the present disclosure.

It should be noted that the terms “first”, “second” and the so on in the description and claims of the present disclosure and the above-mentioned drawings are used to distinguish between different objects but do not indicate a particular order. It should be understood that the numbers used as such may be interchanged where appropriate so that the embodiments of the present disclosure described herein can be implemented in an order other than those illustrated or described herein. In addition, the terms “include”, “have” and any variations thereof are intended to cover non-exclusive inclusions. For example, a process, a method, a system, a product, or a device that includes a series of steps or units is not limited to the listed steps or units, but optionally further includes an unlisted step or unit, or optionally further includes another inherent step or unit of the process, the method, the product, or the device.

### First Embodiment

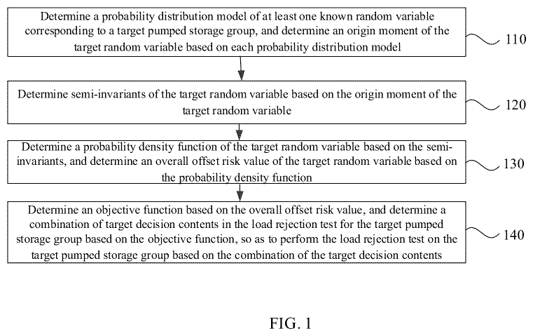

FIG. 1 is a flow diagram illustrating a method for a load rejection test for a pumped storage group according to a first embodiment of the present disclosure. This embodiment is applicable to determining a combination of decision contents in a load rejection test for a pumped storage group, and further performing an optimal load rejection test on the pumped storage group based on the combination of decision contents. The method may be executed by a device for the load rejection test for the pumped storage group. The device for the load rejection test for the pumped storage group may be implemented in the form of hardware and/or software, and the device for the load rejection test the pumped storage group may be configured in electronic equipment such as a computer, a server or a tablet computer. Specifically, referring to FIG. 1, the method specifically includes the following steps.

In step 110, a probability distribution model of at least one known random variable corresponding to the target pumped storage group is determined, and an origin moment of the target random variable is determined based on each probability distribution model.

The target random variable is an undetermined random variable in the load rejection test for the target pumped storage group. In this embodiment, the undetermined random variable may include a group speed, a volute pressure, a group swing, a vibration or a bearing temperature of the pumped storage group during load rejection, which is not limited in this embodiment.

The pumped storage group refers to a synchronous motor having two working modes of power generation and pumping, and each pumped storage group may include a plurality of generators having a pumping function, for example, three, four or ten generators, which is not limited in this embodiment. The target pumped storage group in this embodiment may be a combination of generators in any pumped storage substation.

In this embodiment, the known random variables may include an upper reservoir water level of a pumped storage power station, a lower reservoir water level of the pumped storage power station, a guide vane opening, a bearing bush clearance and the like, which is not limited in this embodiment.

Optionally, in this embodiment, determining the probability distribution model of the at least one known random variable corresponding to the target pumped storage group may include: describing random distributions of the upper reservoir water level and the lower reservoir water level of the pumped storage power station through a Weibull function respectively, so as to obtain a probability distribution model corresponding to the upper reservoir water level of the pumped storage power station and a probability distribution model corresponding to the lower reservoir water level of the pumped storage power station; describing an uncertainty of the guide vane opening through normal distribution, so as to obtain a probability distribution model corresponding to the guide vane opening; and describing random distribution of the bearing bush clearance through a beta function, so as to obtain a probability distribution model corresponding to the bearing bush clearance.

In a specific implementation, the Weibull function may be used to describe the random distribution of the upper reservoir water level of the power station. The expression of the probability density is:

$${f}_{v} ( v ) = \frac{K}{C} {( \frac{v}{C} )}^{K - 1} exp [ - {( \frac{v}{C} )}^{K} ] ,$$

where K represents a shape parameter of Weibull distribution, v represents an actual water level, and C represents a scale parameter.

Further, the Weibull function may also be used to describe the random distribution of the lower reservoir water level of the power station, with a difference that the shape parameter K and the scale parameter C have different values.

Further, a normal distribution may be used to approximate the uncertainty of the guide vane opening, and the probability density function may be described as follows:

$${f}_{Pload} ( {P}_{load} ) = \frac{1}{\sqrt{2 {πσ}_{load}}} exp [ - \frac{{( {P}_{load} - {μ}_{load} )}^{2}}{2 {σ}_{load}^{2}} ] ,$$

where μ_{load} and σ_{load} represent the mean and the variance of the guide vane opening P_{load}, respectively.

Further, the beta function may be used to describe the random distribution of the bearing bush clearance of the hydraulic turbine, and the expression of probability density is:

$${f}_{r} ( r ) = \frac{⌈ ( α + β )}{⌈ ( α ) ⌈ ( β )} {( \frac{r}{{r}_{max}} )}^{α - 1} {( 1 - \frac{r}{{r}_{max}} )}^{β - 1} ,$$

Wherein α and β represent shape parameters of beta distribution, and rₘₐₓ represents the maximum bearing pad clearance.

In an optional implementation of this embodiment, after the probability distribution model of each known random variable is determined, the origin moment of the target random variable may be further determined based on the determined probability distribution model.

Optionally, in this embodiment, determining the origin moment of the target random variable based on each probability distribution model may include: processing each probability distribution model through a point estimation method to obtain values of estimation points for different known random variables corresponding to the target random variable; and determining a probability value corresponding to each estimation point based on each probability distribution model, and determining the origin moment of the target random variable based on each probability value.

In a specific implementation, after obtaining the probability distribution model of each known random variable, central moments λ_{i,j} of each known random variable may be calculated first. Optionally, if the n-dimensional known random variable is X=(X₁, X₂, . . . , Xₙ), then m estimation points are taken from each known random variable Xᵢ(i=1, 2, . . . , n), and i is the number of the known random variables. Based on the mean μᵢ and the variance σᵢ of each known random variable Xᵢ, the estimation points can be expressed as:

$${x}_{i , k} = {μ}_{i} + {ξ}_{i , k} {σ}_{i}$$

where ξ_{i,k} is referred to as a position coefficient.

Exemplarily, if the probability corresponding to each estimation point is ω_{i,k}, there is:

$$\{ \begin{matrix}{\sum }_{k = 1}^{m} {ω}_{i , k} = \frac{1}{n} \\ {\sum }_{i = 1}^{n} {\sum }_{k = 1}^{m} {ω}_{i , k} = 1\end{matrix} ,$$

If λ_{i,j} is the normalized central moment of j order of the known random variable Xᵢ, there is:

$${λ}_{i , j} = \frac{{M}_{j} ( {X}_{i} )}{{( {σ}_{i} )}^{j}} , {M}_{j} ( {X}_{i} ) = {\int }_{- ∞}^{∞} {( {X}_{i} - {μ}_{i} )}^{j} f ( {X}_{i} ) d {X}_{i} ,$$

where f(Xᵢ) represents a probability density function of the known random variable Xᵢ.

Further, a point estimation method of a 2n+1 scheme may be selected to calculate the position coefficient ξ_{i,k} and the probability ω_{i,k} corresponding to each estimation point. Exemplarily, it may be assumed that Y=h(X) is a nonlinear function with X as a variable. Using the Taylor series to expand the function h(Xᵢ) at the mean point μᵢ, and estimating Y at m points with Δ_{i,j}, there is:

$${\sum }_{k = 1}^{m} {ω}_{i , k} ( {ξ}_{i , k} ) = {λ}_{i , j} , i = 1 , 2 , … , n , j = 1 , 2 , … , 2 m - 1.$$

Further, it can be obtained from the equation

$${λ}_{i , j} = \frac{{M}_{j} ( {X}_{i} )}{{( {σ}_{i} )}^{j}}$$

and the equation Mⱼ(Xᵢ)=∫_{-∞}^{∞}(Xᵢ−μᵢ)^{j}f(Xᵢ)dXᵢ that λ_{i,1}=0, λ_{i,2}=1, and λ_{i,3} and λ_{i,4} represent a skewness coefficient and a kurtosis coefficient of Xᵢ respectively. Exemplarily, it may be set that m=3, and three estimation points may be taken for each random variable Xᵢ. If one estimation point is taken as the mean μᵢ of the random variable, and the corresponding position coefficient ξ_{i,3}=0, and the position coefficient ξ_{i,k} and the probability ω_{i,k} of each estimation point may be obtained according to the formulas

$$\{ \begin{matrix}{\sum }_{k = 1}^{m} {ω}_{i , k} = \frac{1}{n} \\ {\sum }_{i = 1}^{n} {\sum }_{k = 1}^{m} {ω}_{i , k} = 1\end{matrix} , \\ {λ}_{i , j} = \frac{{M}_{j} ( {X}_{i} )}{{( {σ}_{i} )}^{j}} , \\ {M}_{j} ( {X}_{i} ) = {\int }_{- ∞}^{∞} {( {X}_{i} - {μ}_{i} )}^{j} f ( {X}_{i} ) d {X}_{i} , and \\ {\sum }_{k = 1}^{m} {ω}_{i , k} ( {ξ}_{i , k} ) = {λ}_{i , j} , i = 1 , 2 , … , n , j = 1 , 2 , … , 2 m - 1 : \{ \begin{matrix}{ξ}_{i , k} = \frac{{λ}_{i , 3}}{2} + {( - 1 )}^{3 - k} \sqrt{{λ}_{i , 4} - \frac{3}{4} {λ}_{i , 3}^{2}} , & k = 1 , 2 \\ {ξ}_{i , 3} = 0 & \end{matrix} , \\ \{ \begin{matrix}{ω}_{i , k} = \frac{{( - 1 )}^{3 - k}}{{ξ}_{i , k} ( {ξ}_{i , 1} - {ξ}_{i , 2} )} , & k = 1 , 2 \\ {ω}_{i , 3} = \frac{1}{n} - \frac{1}{{λ}_{i , 4} - {λ}_{i , 3}^{2}} & \end{matrix} .$$

Further, the value of the estimation point x_{i,k} can be calculated from the equation x_{i,k}=μᵢ+ξ_{i,k}σᵢ based on the variance σᵢ and the mean μᵢ of Xᵢ.

Further, the value of the estimation point x_{i,k} obtained by using the known random variable may be used to obtain values of different known random variable estimation points corresponding to the target random variables through simulation calculation.

Further, the origin moments E(Y^{l}) of each target random variable Y may be calculated based on the probabilities ω_{i,k} corresponding to the known random variable estimation points.

$$E ( {Y}^{l} ) = {\sum }_{i = 1}^{n} {\sum }_{k = 1}^{m} {{ω}_{i , k} [ h ( {μ}_{1} , {μ}_{2} , … , {x}_{i , k} , … , {μ}_{n} ) ]}^{l} ,$$

where l represents the order of the origin moment, when l=1, E(Y^{l}) represents the mean of Y, and when l=2, the standard deviation of Y is σ_{Y}=\sqrt{E(Y²)−E(Y)²}.

In step 120, semi-invariants of the target random variable are determined based on the origin moment of the target random variable.

In an optional implementation of this embodiment, after the origin moment of each target random variable is determined based on the probability distribution model of each known random variable, the semi-invariants of the target random variable may be further determined based on the determined origin moment of the target random variable.

Optionally, in this embodiment, determining the semi-invariants of the target random variable based on the origin moment of the target random variable includes: determining the semi-invariants of the target random variable through the following formula:

$$\{ \begin{matrix}{x}_{l} = E ( X ) \\ {x}_{l + 1} = E ( {X}^{l + 1} ) - {\sum }_{j = 1}^{l} \frac{l !}{j ! ( l - j ) !} \\ E ( {X}^{j} ) {x}_{l - j + 1} , l = 1 , 2 , …\end{matrix} ,$$

where X represents the target random variable, xₗ represents the semi-invariants of the target random variable, and E(X^{j}) represents the origin moment of the target random variable.

In step 130, a probability density function of the target random variable is determined based on the semi-invariants, and an overall offset risk value of the target random variable is determined based on the probability density function.

In an optional implementation of this embodiment, after the semi-invariants of each target random variable are determined, the probability density function of the target random variable may be further determined based on the determined order semi-invariant, and the overall offset risk value of the target random variable may be determined based on the determined probability density function.

Optionally, in this embodiment, determining the probability density function of the target random variable based on the semi-invariants, and determining the overall offset risk value of the target random variable based on the probability density function includes: performing series expansion on the semi-invariants to obtain a quantile of a probability distribution function of the target random variable, and the probability distribution function and the probability density function of the target random variable; determining an offset risk value of the target random variable based on the probability density function of the target random variable; and accumulating the offset risk value, and weighting the accumulated offset risk value to obtain the overall offset risk value of the target random variable.

In a specific implementation, the quantile of the target random variable X may be first taken as θ, and the quantile of the target random variable probability distribution function F(x) may be expressed as:

$${x}_{θ} \approx {z}_{θ} + \frac{{z}_{θ}^{2} - 1}{6} {χ}_{3} + \frac{{z}_{θ}^{3} - 3 {z}_{θ}}{24} {χ}_{4} - \frac{2 {z}_{θ}^{3} - 5 {z}_{θ}}{36} {χ}_{3}^{2} + \frac{{z}_{θ}^{4} - 6 {z}_{θ}^{2} + 3}{120} {χ}_{5} - \frac{{z}_{θ}^{4} - 5 {z}_{θ}^{2}}{24} {χ}_{2} {χ}_{3} + \frac{12 {z}_{θ}^{4} - 53 {z}_{θ}^{2}}{324} {χ}_{3}^{3} ,$$

where z_{θ}=φ⁻¹(θ), φ represents the probability distribution function of the standard normal distribution function N(0,1), and z_{θ} is the corresponding quantile of the quantile e in the standard normal distribution.

Further, the probability distribution function F(x) and the probability density function f(x) of the target random variable X can be obtained based on the relationship of x_{θ}=F⁻¹(θ).

Further, the risk characteristic value R_{CVaR}_{_{β}}(x) may be calculated.

Exemplarily, x may be a combination of decision variables, and y may be a combination of undetermined random variables. Given that the probability density function of y is ρ(y), the cumulative distribution function for each target random variable whose offset risk loss f(x, y) does not exceed the critical value α is expressed as:

$$ψ ( x , α ) = {\int }_{f ( x , y ) \leq α} ρ ( y ) dy .$$

For a given confidence coefficient β, the risk value R_{VaR}_{_{β}}(x) can be expressed as:

$${R}_{{VaR}_{β}} ( x ) = min \{ α ∈ R : ψ ( x , α ) \geq β \}$$

where R represents a real number. It should be noted that the confidence coefficient β involved in this embodiment is preset, for example, is preset to 0.99 or 0.95, which is not limited in this embodiment. Meanwhile, the critical value α is calculated by the preset confidence coefficient β. By way of example, a plurality of points are calculated through ψ(x, a)=∫_{f(xy)≤α}p(y)dy. The loss values are 1, 2, 3, 4, 5, 6, 7, 8, 9 and 10, respectively. The preset confidence coefficient @ is 0.9, that is, the risk calculated by the risk value R_{VaR}_{_{β}}(x) is 9. It means that there is a probability greater than or equal to 90% that the risk loss is less than or equal to 9, in which 9 is the critical value.

Further, a transformation function may be constructed as below:

$$F ( x , α ) = α + \frac{1}{1 - β} \int {[ f ( x , y ) - α ]}^{+} ρ ( y ) d y , {where [ f ( x , y ) - α ]}^{+} = max \{ f ( x , α ) - α , 0 \} .$$

It can be understood that when the transformation function takes the minimum value, α represents the value of R_{VaR}_{_{β}}(x), F(x,a) represents the value of R_{CVaR}_{_{β}}(x):

R_{VaR}_{_{B}}(x)=α, and

R_{CVaR}_{_{β}}(x)=minF(x,α).

It should be noted that in this embodiment, each target random variable risk value is represented by R_{CVaR}_{_{β}}(x).

Further, the overall offset risk value of the target random variable can be calculated. For example, the offset risk value V_{RISK}ⁱ of the i^{th} target random variable can be represented by the value of R_{CVaR}_{_{β}}ⁱ(x), that is:

V_{RISK}ⁱ=R_{CVAR}_{_{β}}ⁱ(x).

According to the cumulative characteristics of risks, the overall offset risk index V_{RISK}^{S} of the target random variable can be expressed as:

$${V}_{RISK}^{S} = {\partial }^{i} \cdot {V}_{RISK}^{i} ,$$

where ∂ⁱ represents a weighting coefficient used to reflect the degree of influence of each target random variable on the overall offset risk. It should be noted that, in this embodiment, the weighting coefficient ∂ⁱ can be determined according to the importance of an undetermined random variable (group speed, volute pressure, group swing, vibration and bearing temperature during the load rejection) to the risk determination. Since the group speed and the volute pressure are the most direct indexes that affect the safety of the group load rejection process, they are assigned with the greatest weighting coefficient, and the group swing, the vibration and the bearing temperature are assigned with smaller weighting coefficients. It can be understood that if the objective function has different weighting coefficients, different optimization schemes can be obtained. For example, in this embodiment, the group speed may be assigned with a weighting coefficient of 0.3, the volute pressure may be assigned with a weighting coefficient of 0.25, the group swing may be assigned with a weighting coefficient of 0.2, the vibration may be assigned with a weighting coefficient of 0.15, and the bearing temperature may be assigned with a weighting coefficient of 0.1.

In step 140, an objective function is determined based on the overall offset risk value, and a combination of target decision contents is determined in the load rejection test for the target pumped storage group based on the objective function, so as to perform the load rejection test on the target pumped storage group based on the combination of the target decision contents.

In an optional implementation of this embodiment, after the overall offset risk value of each target random variable is determined based on the probability density function of each target random variable, the objective function may be further determined based on the determined overall offset risk value, and the combination of the target decision contents in the load rejection test for the target pumped storage group may be determined based on the objective function.

The combination of the target decision contents may include a stator current and a rotor current.

Optionally, in this embodiment, determining the objective function based on the overall offset risk value, and determining the combination of the target decision contents in the load rejection test for the target pumped storage group based on the objective function includes: sorting the overall offset risk value to obtain a target overall offset risk value; determining the target overall offset risk value as the objective function, and setting constraints corresponding to the target random variable; and obtaining the combination of the target decision contents based on the objective function and the constraints.

In a specific implementation, the determined overall offset risk values may be sorted to determine a minimum overall offset risk value, and the minimum overall offset risk value may be determined as the objective function, which may be expressed as:

min(V_{RISK}^{S}).

Further constraints may be set. Exemplarily, risk constraints of the target random variable may be expressed as below:

R_{VaR}_{_{B}}ⁱ(x)≤ΔV_{N}ⁱ,
where R_{VaR}_{_{B}}ⁱ(x) represents the actual offset risk value of the i^{th} target random variable, and ΔV_{N}ⁱ represents an offset alert threshold set for the i^{th} target random variable.

The guide vane closing time constraint may be expressed as below:

S≤S_{T},
where S represents an actual closing time of the guide vane, and S_{T} represents a setting valve of the closing time of the guide vane.

Servomotor round-trip frequency constraint may be expressed as below:

N≤N_{T},
where N represents an actual round-trip time of the servomotor, and N_{T} represents a setting value of the round-trip frequency of the servomotor.

The governor adjustment time constraint may be expressed as below:

T≤T_{A},
where T represents an actual adjustment time of the governor, and T_{A} represents a setting value of the adjustment time of the governor.

Further, the optimal combination of the decision variables (stator current and rotor current) can be solved by a quantum-behaved particle swarm algorithm. In the specific implementation, parameters such as the swarm size, dimension and iteration times can be designed according to the actual situation, present positions of the particles in the particle swarm can be initialized, and it is set that Pᵢ(0)=Xᵢ(0) and P_{g}(0)=min {X₁ (0), X₂ (0) . . . . X_{M}(0)}.

Further, a position movement amount S_{mbest}(t+1) of the particle swarm can be calculated. Fitness values of the particles in the particle swarm can be calculated based on the designed objective function, and for each particle, its fitness value is compared with the preceding value, and for the minimization problem, if the present value is less than the preceding value, the preceding value is replaced by the present value, otherwise, the preceding value is retained.

Further, a present global optimal position P_{g}(t) of the swarm may be calculated. g represents a particle with the global optimal position (g∈{1,2, . . . . M}). The global optimal position of the previous iteration P_{g}(t-1) is compared with the present global optimal position P_{g}(t), and the minimum value is retained in P_{g}(t), that is, the objective function.

Further, the random points X_{PP}ⁱ(t) of each particle in the swarm may be calculated, and the new position Xᵢ(t+1) of each particle, i.e., the combination of decision variables, may be updated. Further, it may be determined whether the iteration times are reached, and if so, the loop is ended, otherwise, the position movement amount of the particle swarm is returned to be calculated and the solving process is repeated to obtain the final new position Xᵢ (t+1) of the particle, that is, the combination of the decision variables is obtained.

In the technical solution provided by this embodiment, the probability distribution model of the at least one known random variable corresponding to the target pumped storage group is determined, the origin moment of the target random variable is determined based on each probability distribution model, the semi-invariants of the target random variable are determined based on the origin moment of the target random variable, the probability density function of the target random variable is determined based on the semi-invariants, the overall offset risk value of the target random variable is determined based on the probability density function, the objective function is determined based on the overall offset risk value, and the combination of the target decision contents in the load rejection test for the target pumped storage group is determined based on the objective function, so as to perform the load rejection test on the target pumped storage group based on the combination of the target decision contents. As a result, the combination of decision contents in the load rejection test for the pumped storage group can be accurately determined, and an optimal load rejection test on the pumped storage group can be performed.

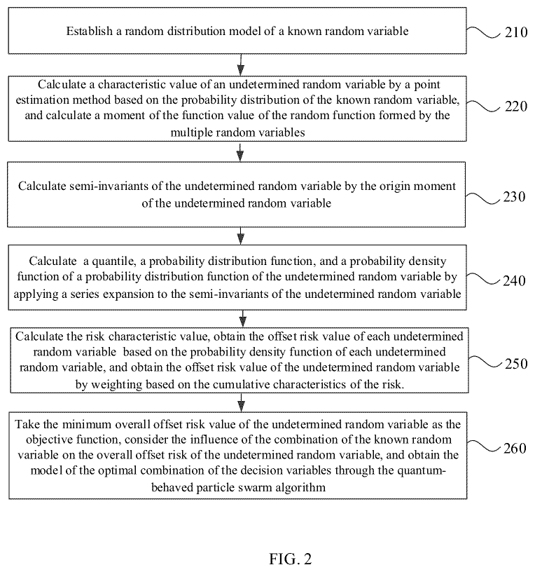

In order to better understand the method for the load rejection test for the pumped storage group according to this embodiment, FIG. 2 shows a flow diagram illustrating the method for the load rejection test for the pumped storage group according to the first embodiment of the present disclosure. Referring to FIG. 2, the method mainly includes the following steps.

In step 210, a random distribution model of a known random variable is established.

In step 220, a characteristic value of an undetermined random variable is calculated by a point estimation method based on the probability distribution of the known random variable, and a moment of the function value of the random function formed by the multiple random variables is calculated.

In step 230, semi-invariants of the undetermined random variable are calculated by the origin moment of the undetermined random variable.

In step 240, a quantile, a probability distribution function, and a probability density function of a probability distribution function of the undetermined random variable are calculated by applying a series expansion to the semi-invariants of the undetermined random variable.

In step 250, the risk characteristic value is calculated, and the offset risk value of each undetermined random variable is obtained based on the probability density function of each undetermined random variable. Based on the cumulative characteristics of the risk, the offset risk value of the undetermined random variable is obtained by weighting.

In step 260, the minimum overall offset risk value of the undetermined random variable is taken as the objective function, and the influence of the combination of the known random variable on the overall offset risk of the undetermined random variable is considered. The model of the optimal combination of the decision variables are obtained through the quantum-behaved particle swarm algorithm.

In this embodiment, the combination of the decision variables includes the stator current and the rotor current. The combination of the known random variables includes the upper reservoir water level of the power station, the lower reservoir water level of the power station, the guide vane opening and the bearing bush clearance. The combination of the undetermined random variables includes: the group speed, the volute pressure, the group swing, the vibration and the bearing temperature during load rejection.

According to the technical solution provided by this embodiment, aiming at the randomness of the hydraulic factor, the mechanical and electrical parameters of the group before load rejection, a method for calculating the overall offset risk of the group random variable is proposed. The method first transforms the probability problem of the random variable into the deterministic problem, and then transforms the statistical characteristic value into the probability distribution of the objective function, so as to obtain the mapping relationship between the random variable and the objective function. Taking the minimum risk as the optimization target, and the stator current and rotor current as the decision variables, considering the actual working condition constraints of the group, the optimal coordination model for the load rejection test for the pumped storage generators is established through the quantum-behaved particle swarm algorithm. The technical solution provided by the embodiment of the present disclosure can more comprehensively reflect the dynamic characteristics of the load rejection process of the pumped storage group, and provide a reference basis for evaluating the load rejection risk in advance.

### Second Embodiment

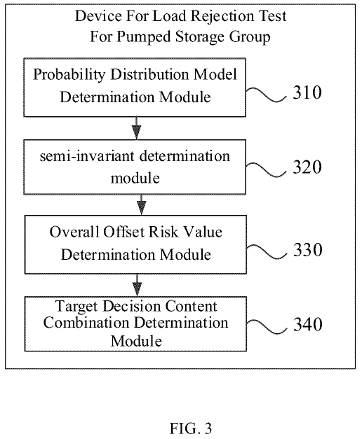

FIG. 3 is a schematic diagram illustrating a device for a load rejection test for a pumped storage group according to a second embodiment of the present disclosure. As shown in FIG. 3, the device includes a probability distribution model determination module 310, a semi-invariant determination module 320, an overall offset risk value determination module 330, and a target decision content combination determination module 340.

The probability distribution model determination module 310 is configured to determine a probability distribution model of at least one known random variable corresponding to a target pumped storage group, and determine an origin moment of the target random variable based on each probability distribution model. The target random variable is an undetermined random variable in the load rejection test for the target pumped storage group.

The semi-invariant determination module 320 is configured to determine semi-invariants of the target random variable based on the origin moment of the target random variable.

The overall offset risk value determination module 330 is configured to determine a probability density function of the target random variable based on the semi-invariants, and determine an overall offset risk value of the target random variable based on the probability density function.

The target decision content combination determination module 340 is configured to determine an objective function based on the overall offset risk value, and determine a combination of target decision contents in the load rejection test for the target pumped storage group based on the objective function, so as to perform the load rejection test on the target pumped storage group based on the combination of the target decision contents.

In the technical solution provided by this embodiment, the probability distribution model of the at least one known random variable corresponding to the target pumped storage group is determined by the probability distribution model determination module, and the origin moment of the target random variable is determined based on each probability distribution model by the probability distribution model determination module. The target random variable is an undetermined random variable in the load rejection test for the target pumped storage group. The semi-invariants of the target random variable are determined based on the origin moment of the target random variable by the semi-invariant determination module. The probability density function of the target random variable is determined based on the semi-invariants by the overall offset risk value determination module, and the overall offset risk value of the target random variable is determined based on the probability density function by overall offset risk value determination module. The objective function is determined based on the overall offset risk value by the target decision content combination determination module, and the target decision content combination determination module determines the combination of the target decision contents in the load rejection test for the target pumped storage group based on the objective function, so as to perform the load rejection test on the target pumped storage group based on the combination of the target decision contents. As a result, the combination of decision contents in the load rejection test for the pumped storage group can be accurately determined, and an optimal load rejection test on the pumped storage group can be performed.

In an optional implementation of this embodiment, the known random variables may include an upper reservoir water level of a pumped storage power station, a lower reservoir water level of the pumped storage power station, a guide vane opening, a bearing bush clearance and the like, which is not limited in this embodiment. The target random variable includes at least one of a group speed, a volute pressure, a group swing, vibration, and a bearing temperature of the pumped storage group during load rejection.

In an optional implementation of this embodiment, the probability distribution model determination module 310 is specifically configured to: describe random distributions of the upper reservoir water level and the lower reservoir water level of the pumped storage power station through a Weibull function respectively, and obtain a probability distribution model corresponding to the upper reservoir water level of the pumped storage power station and a probability distribution model corresponding to the lower reservoir water level of the pumped storage power station; describe an uncertainty of the guide vane opening through normal distribution, and obtain a probability distribution model corresponding to the guide vane opening; and describe random distribution of the bearing bush clearance through a beta function, and obtain a probability distribution model corresponding to the bearing bush clearance.

In an optional implementation of this embodiment, the probability distribution model determination module 310 is further specifically configured to: process each probability distribution model through a point estimation method to obtain values of estimation points for different known random variables corresponding to the target random variable; and determine a probability value corresponding to each estimation point based on each probability distribution model, and determine the origin moment of the target random variable based on each probability value.

In an optional implementation of this embodiment, the order semi-invariant determination module 320 is specifically configured to determine the semi-invariants of the target random variable through the following formula:

$$\{ \begin{matrix}{x}_{l} = E ( X ) \\ {x}_{l + 1} = E ( {X}^{l + 1} ) - {\sum }_{j = 1}^{l} \frac{l !}{j ! ( l - j ) !} \\ E ( {X}^{j} ) {x}_{l - j + 1} , l = 1 , 2 , …\end{matrix} ,$$

where X represents the target random variable, xₗ represents the semi-invariants of the target random variable, and E(X^{j}) represents the origin moment of the target random variable.

In an optional implementation of this embodiment, the overall offset risk value determination module 330 is specifically configured to perform series expansion on the semi-invariants to obtain a quantile of a probability distribution function of the target random variable, and the probability distribution function and the probability density function of the target random variable; determine an offset risk value of the target random variable based on the probability density function of the target random variable; and accumulate the offset risk value, and weight the accumulated offset risk value to obtain the overall offset risk value of the target random variable.

In an optional implementation of this embodiment, the target decision content combination determination module 340 is specifically configured to sort the overall offset risk value to obtain a target overall offset risk value; determine the target overall offset risk value as the objective function, and set constraints corresponding to the target random variable; and obtain the combination of the target decision contents based on the objective function and the constraints The combination of the target decision contents includes a stator current and a rotor current.

The device for the load rejection test for the pumped storage group provided in the embodiments of the present disclosure can implement the method for the load rejection test for the pumped storage group provided in any of the embodiments of the present disclosure, has the corresponding functional modules to execute the method, and has the same beneficial effects as the method.

### Three Embodiment

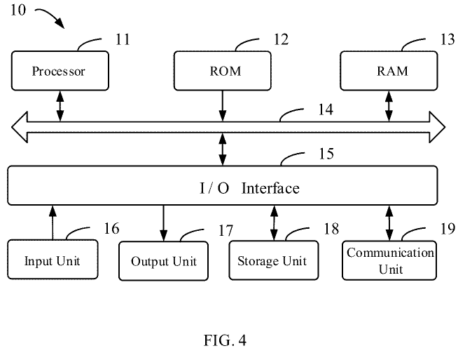

FIG. 4 is a schematic diagram illustrating a configuration of an electronic apparatus 10 that can be used to implement an embodiment of the present disclosure. The electronic apparatus is intended to refer to various forms of digital computers, such as laptop computers, desktop computers, workstations, personal digital assistants, servers, blade servers, mainframe computers, and other suitable computers. The electronic apparatus may also refer to various forms of mobile devices, such as personal digital assistants, cellular phones, smartphones, wearable devices (e.g., helmets, glasses, watches, etc.), and other similar computing devices. The components shown herein, their connections and relationships, and their functions are examples only and are not intended to limit the implementation of the present disclosure described and/or claimed herein.

As shown in FIG. 4, the electronic apparatus 10 includes at least one processor 11, and a memory communicatively connected to the at least one processor 11, such as a read only memory (ROM) 12, a random access memory (RAM) 13, and the like. The memory stores a computer program executable by the at least one processor, and the processor 11 may perform various appropriate actions and processes based on the computer program stored in the ROM 12 or the computer program loaded from the storage group 18 into the RAM 13. In RAM 13. In the RAM 13, various programs and data required for operation of the electronic apparatus 10 may also be stored. The processor 11, the ROM 12 and the RAM 13 are connected to each other through a bus 14. An input/output (I/O) interface 15 is also connected to the bus 14.

A plurality of components in the electronic apparatus 10 are connected to the I/O interface 15, including: an input unit 16, such as a keyboard, a mouse, and the like; an output unit 17, such as various types of displays, speakers, and the like; a storage group 18, such as a magnetic disk, an optical disk, or the like; and a communication unit 19, such as a network card, a modem, a wireless communication transceiver, or the like. The communication unit 19 allows the electronic apparatus 10 to exchange information/data with other devices through a computer network such as the Internet and/or various telecommunication networks.

The processor 11 may be a variety of general and/or dedicated processing components having processing and computing capabilities. Some examples of the processor 11 include, but are not limited to, a central processing unit (CPU), a graphics processing unit (GPU), various specialized artificial intelligence (AI) computing chips, various processors that run machine learning model algorithms, a digital signal processor (DSP), and any suitable processor, controller, microcontroller, and the like. The processor 11 implements each method and process described above, such as the method for the load rejection test for the pumped storage group.

In some embodiments, the method for the load rejection test for the pumped storage group may be implemented as a computer program, which is tangibly included in a computer-readable storage medium, such as the storage group 18. In some embodiments, part or all of the computer program may be loaded and/or installed on the electronic apparatus through the ROM 12 and/or the communication unit. When the computer program is loaded into the RAM 13 and executed by the processor 11, one or more steps of the method for the load rejection test for the pumped storage group described above may be performed. Alternatively, in other embodiments, the processor 11 may be configured to perform the method for the load rejection test for the pumped storage group in any other suitable manner (e.g., by means of firmware).

Various implementations of the systems and techniques described above may be implemented in digital electronic circuit systems, integrated circuit systems, field programmable gate arrays (FPGAs), application specific integrated circuits (ASICs), application specific standard products (ASSPs), systems of system-on-a-chip (SOC), load programmable logic devices (CPLD), computer hardware, firmware, software, and/or combinations thereof. These various embodiments may include: implementation in one or more computer programs that may be implemented and/or interpreted on a programmable system including at least one programmable processor, which may be a dedicated or general-purpose programmable processor, that may receive data and instructions from the storage system, the at least one input device, and the at least one output device, and transmit the data and instructions to the storage system, the at least one input device, and the at least one output device.

Computer programs for implementing the method according to the present disclosure may be written in any combination of one or more programming languages. These computer programs may be provided to a processor of a general-purpose computer, a special-purpose computer, or other programmable data processing device such that the computer program when executed by the processor causes the functions/operations set forth in the flowchart and/or the block diagram to be performed. The computer program may be executed entirely on the machine, partially on the machine, partially on the machine as a stand-alone software package and partially on a remote machine or entirely on a remote machine or server.

In the context of the present disclosure, the computer-readable storage medium may be a tangible medium that may contain or store a computer program for use by or in conjunction with an instruction execution system, device or apparatus. The computer-readable storage medium may include, but is not limited to, an electronic, magnetic, optical, electromagnetic, infrared, or semiconductor system, device, or apparatus, or any suitable combination of the foregoing. Alternatively, the computer-readable storage medium may be a machine-readable signalling medium. More specific examples of machine-readable storage media may include an electrical connection based on one or more wires, aa portable computer disc, a hard disc, a random access memory (RAM), a read-only memory (ROM), an erasable programmable read-only memory (EPROM or flash memory), an optical fiber, a convenient compact disc read-only memory (CD-ROM), an optical storage device, a magnetic storage device, or any suitable combination thereof.

To provide interaction with a user, the systems and techniques described herein may be implemented on an electronic apparatus having: a display device (e.g., a CRT (cathode ray tube) or LCD (liquid crystal display) monitor) for displaying information to the user; and a keyboard and a pointing device (e.g., a mouse or a trackball) by which the user can provide input to the electronic apparatus. Other types of devices may also be used to provide interaction with the user. For example, the feedback provided to the user may be any form of sensory feedback (e.g., visual feedback, auditory feedback, or haptic feedback). The input from the user may be received in any form including acoustic input, voice input, or, haptic input.

The systems and techniques described herein may be implemented in a computing system that includes a back-end component (e.g., as a data server), or a computing system that includes a middleware component (e.g., an application server), or a computing system that includes a front-end component (e.g., a user's computer that has a graphical user interface or web browser through which a user can interact with any of the implementations of the systems and techniques described herein), or any combination of such back-end, middleware, or front-end components. embodiments of the systems and techniques described herein), or in a computing system that includes any combination of such back-end components, middleware components, or front-end components. The components of the system may be interconnected via digital data communications (e.g., a communications network) in any form or medium. Examples of communication networks include: a local area network (LANs), a wide area network (WANs), a blockchain network, and the Internet.

The computing system may include a client and a server. The client and the server are generally remote from each other and typically interact over a communication network. The client-server relationship is created by computer programs that run on corresponding computers and have a client-server relationship with each other. The server can be a cloud server, also known as a cloud computing server or cloud host, which is a host product in the cloud computing service system to solve the defects of the traditional physical host and VPS services, which are difficult to manage and weak in business scalability.

It should be understood that steps may be reordered, added or deleted using various forms of the process shown above. For example, the steps described in the present disclosure may be performed in parallel or sequentially or in a different order, as long as the desired result of the technical solution of the present disclosure can be achieved, which is not limited herein.

The above specific embodiments are not intended to limit the scope of protection of the present disclosure. It should be appreciated by persons of ordinary skill in the art that various modifications, combinations, sub-combinations and substitutions may be made according to design requirements and other factors. Any modifications, equivalent substitutions and improvements, etc. made within the spirit and principles of the present disclosure shall be included in the scope of protection of the present disclosure.

1. A method for a load rejection test for a pumped storage group, the method comprising:
determining a probability distribution model of at least one known random variable corresponding to a target pumped storage group, and determining an origin moment of the target random variable based on each probability distribution model, the target random variable being an undetermined random variable in the load rejection test for the target pumped storage group, the target random variable including at least one of a group speed, a volute pressure, a group swing, a vibration or a bearing temperature of the pumped storage group during load rejection;
determining semi-invariants of the target random variable based on the origin moment of the target random variable;
determining a probability density function of the target random variable based on the semi-invariants, and determining an overall offset risk value of the target random variable based on the probability density function; and
determining an objective function based on the overall offset risk value, and determining a combination of target decision contents in the load rejection test for the target pumped storage group based on the objective function, so as to perform the load rejection test on the target pumped storage group based on the combination of the target decision contents;
wherein the known random variable comprises at least one of an upper reservoir water level of a pumped storage power station, a lower reservoir water level of the pumped storage power station, a guide vane opening or a bearing bush clearance; and
wherein determining the probability distribution model of the at least one known random variable corresponding to the target pumped storage group comprises includes:
describing random distributions of the upper reservoir water level and the lower reservoir water level of the pumped storage power station through a Weibull function respectively, so as to obtain a probability distribution model corresponding to the upper reservoir water level of the pumped storage power station and a probability distribution model corresponding to the lower reservoir water level of the pumped storage power station;
describing an uncertainty of the guide vane opening through normal distribution, so as to obtain a probability distribution model corresponding to the guide vane opening; and
describing random distribution of the bearing bush clearance through a beta function, so as to obtain a probability distribution model corresponding to the bearing bush clearance.

2. The method of claim 1, wherein determining the origin moment of the target random variable based on each probability distribution model includes:
processing each probability distribution model through a point estimation method to obtain values of estimation points for different known random variables corresponding to the target random variable; and
determining a probability value corresponding to each estimation point based on each probability distribution model, and determining the origin moment of the target random variable based on each probability value.

3. The method of claim 1, wherein determining the semi-invariants of the target random variable based on the origin moment of the target random variable includes:
determining the semi-invariants of the target random variable through the following formula:
$$\{ \begin{matrix}{x}_{l} = E ( X ) \\ {x}_{l + 1} = E ( {X}^{l + 1} ) - {\sum }_{j = 1}^{l} \frac{l !}{j ! ( l - j ) !} , \\ E ( {X}^{j} ) {x}_{l - j + 1} , l = 1 , 2 , …\end{matrix}$$
where X represents the target random variable, xₗ represents the semi-invariants of the target random variable, and E(X^{j}) represents the origin moment of the target random variable.

4. The method of claim 1, wherein determining the probability density function of the target random variable based on the semi-invariants, and determining the overall offset risk value of the target random variable based on the probability density function include:
performing series expansion on the semi-invariants to obtain a quantile of a probability distribution function of the target random variable, and the probability distribution function and the probability density function of the target random variable;
determining an offset risk value of the target random variable based on the probability density function of the target random variable; and
accumulating the offset risk value, and weighting the accumulated offset risk value to obtain the overall offset risk value of the target random variable.

5. The method of claim 1, wherein determining the objective function based on the overall offset risk value, and determining the combination of the target decision contents in the load rejection test for the target pumped storage group based on the objective function includes:
sorting the overall offset risk value to obtain a target overall offset risk value;
determining the target overall offset risk value as the objective function, and setting constraints corresponding to the target random variable; and
obtaining the combination of the target decision contents based on the objective function and the constraints; and
wherein the combination of the target decision contents comprises a stator current and a rotor current.

6. A device for a load rejection test for a pumped storage group, comprising:
a probability distribution model determination module configured to determine a probability distribution model of at least one known random variable corresponding to a target pumped storage group, and determine an origin moment of the target random variable based on each probability distribution model, the target random variable being an undetermined random variable in the load rejection test for the target pumped storage group, the target random variable comprising at least one of a group speed, a volute pressure, a group swing, a vibration or a bearing temperature of the pumped storage group during load rejection;
a semi-invariant determination module configured to determine semi-invariants of the target random variable based on the origin moment of the target random variable;
an overall offset risk value determination module configured to determine a probability density function of the target random variable based on the semi-invariants, and determine an overall offset risk value of the target random variable based on the probability density function;
a target decision content combination determination module configured to determine an objective function based on the overall offset risk value, and determine a combination of target decision contents in the load rejection test for the target pumped storage group based on the objective function, so as to perform the load rejection test on the target pumped storage group based on the combination of the target decision contents;
wherein the known random variable comprises at least one of an upper reservoir water level of a pumped storage power station, a lower reservoir water level of the pumped storage power station, a guide vane opening or a bearing bush clearance; and
wherein the probability distribution model determination module is specifically configured to:
describe random distributions of the upper reservoir water level and the lower reservoir water level of the pumped storage power station through a Weibull function respectively, so as to obtain a probability distribution model corresponding to the upper reservoir water level of the pumped storage power station and a probability distribution model corresponding to the lower reservoir water level of the pumped storage power station;
describe an uncertainty of the guide vane opening through normal distribution, and obtain a probability distribution model corresponding to the guide vane opening; and
describe random distribution of the bearing bush clearance through a beta function, and obtain a probability distribution model corresponding to the bearing bush clearance.

7. An electronic apparatus, comprising:
at least one processor; and
a memory communicatively connected to the at least one processor,
wherein the memory stores a computer program executable by the at least one processor, and the computer program, when executed by the at least one processor, causes the at least one processor to implement the method of claim 1.

8. A computer-readable storage medium configured to cause, when executed by a processor, the processor to implementing the method of claim 1.
